(19) United States
(12) Patent Application Publication
(10) Pub. No.: US 2013/0320349 A1
(43) Pub. Date: Dec. 5, 2013

(54) IN-SITU BARRIER OXIDATION TECHNIQUES AND CONFIGURATIONS

(71) Applicants: Paul Saunier, Dallas, TX (US); Andrew A. Ketterson, Dallas, TX (US)

(72) Inventors: Paul Saunier, Dallas, TX (US); Andrew A. Ketterson, Dallas, TX (US)

(73) Assignee: TRIQUINT SEMICONDUCTOR, INC., Hillsboro, OR (US)

(21) Appl. No.: 13/484,215

(22) Filed: May 30, 2012

(51) Int. Cl. H01L 21/335; H01L 21/336; H01L 29/778

(52) U.S. Cl. 257/76; 257/194; 438/285; 438/172; 257/E29.246; 257/E21.409; 257/E21.403

(57) ABSTRACT

Embodiments of the present disclosure describe apparatuses, methods, and systems of an integrated circuit (IC) device. The IC device may include a buffer layer disposed on a substrate, the buffer layer including gallium (Ga) and nitrogen (N), a barrier layer disposed on the buffer layer, the barrier layer including aluminum (Al) and nitrogen (N), wherein the barrier layer includes an oxidized portion of the barrier layer, a gate dielectric disposed on the oxidized portion of the barrier layer, and a gate electrode disposed on the gate dielectric, wherein the oxidized portion of the barrier layer is disposed in a gate region between the gate electrode and the buffer layer.

### FIELD

Embodiments of the present disclosure generally relate to the field of integrated circuits, and more particularly, to in-situ barrier oxidation techniques and configurations.

### BACKGROUND

Presently, group III-Nitride-based transistors such as gallium nitride (GaN)-based high electron mobility transistors (HEMTs) are typically Depletion-mode (D-mode) devices, which use a negative gate voltage with respect to source voltage in order to pinch-off current flow in the transistor channel. However, Enhancement-mode (E-mode) devices, which use a positive gate voltage with respect to source voltage in order to pinch-off current flow, may be desirable for applications such as power switching. However, conventional recess and deposition processes to form an E-mode device may induce traps or other defects at an interface of a gate terminal and channel of the transistor.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section view of an integrated circuit (IC) device, according to various embodiments.

FIG. 2 schematically illustrates a cross-section view of another IC device, according to various embodiments.

FIG. 3 schematically illustrates a cross-section view of an IC device subsequent to formation of a stack of layers on a substrate, according to various embodiments.

FIG. 4 schematically illustrates a cross-section view of an IC device subsequent to formation of a source and drain, according to various embodiments.

FIG. 5 schematically illustrates a cross-section view of an IC device subsequent to forming an oxidized portion of the barrier layer without recessing the barrier layer, according to various embodiments.

FIG. 6 schematically illustrates a cross-section view of an IC device subsequent to recessing a barrier layer and forming an oxidized portion of the barrier layer, according to various embodiments.

FIG. 7 schematically illustrates a cross-section view of another IC device subsequent to forming an oxidized portion of a barrier layer without recessing the barrier layer, according to various embodiments.

FIG. 8 schematically illustrates a cross-section view of an IC device subsequent to forming an oxidized portion of a barrier layer over another barrier layer that serves as an oxidation-stop layer during an oxidation process, according to various embodiments.

FIG. 9 schematically illustrates a cross-section view of an IC device subsequent to forming an oxidized portion of a barrier layer that serves as an etch-stop layer during a recessing process, according to various embodiments.

FIG. 10 schematically illustrates a cross-section view of another IC device subsequent to forming an oxidized portion of a barrier layer that serves as an etch-stop layer during a recessing process, according to various embodiments.

FIG. 11 schematically illustrates a cross-section view of another IC device subsequent to oxidizing a top barrier layer, according to various embodiments.

FIG. 12 schematically illustrates a cross-section view of an IC device subsequent to formation of a gate terminal on the oxidized portion of a barrier layer, according to various embodiments.

FIG. 13 is a flow diagram of a method for fabricating an IC device, according to various embodiments.

FIG. 14 schematically illustrates an example system including an IC device, according to various embodiments.

### DETAILED DESCRIPTION

Embodiments of the present disclosure provide in-situ barrier oxidation techniques and configurations. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed, disposed, or otherwise configured on a second layer,” may mean that the first layer is formed, disposed, or otherwise configured over the second layer, and at least a part of the first layer may be in direct contact (e.g., direct physical and/or electrical contact) or indirect contact (e.g., having one or more other layers between the first layer and the second layer) with at least a part of the second layer.

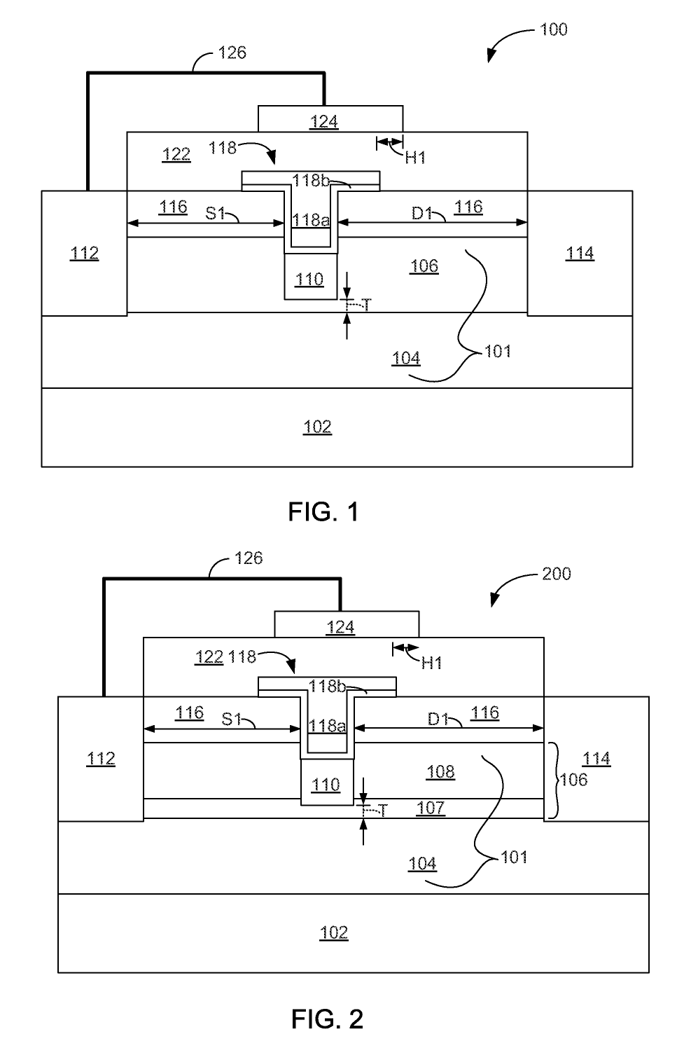

FIG. 1 schematically illustrates a cross-section view of an integrated circuit (IC) device 100, according to various embodiments. The IC device 100 may be fabricated on a substrate 102. The substrate 102 generally includes a support material upon which a stack of layers (or simply “stack 101”) is deposited. In an embodiment, the substrate 102 includes silicon (Si), silicon carbide (SiC), aluminum oxide (Al₂O₃) or “sapphire,” gallium nitride (GaN), and/or aluminum nitride (AlN). Other materials including suitable group II-VI and group III-V semiconductor material systems can be used for the substrate 102 in other embodiments. In an embodiment, the substrate 102 may be composed of any material or combination of materials upon which material of the buffer layer 104 can be epitaxially grown.

The stack 101 formed on the substrate 102 may include epitaxially deposited layers of different material systems that form one or more heterojunctions/heterostructures. The layers of the stack 101 may be formed in situ. That is, the stack 101 may be formed on the substrate 102 in manufacturing equipment (e.g., a chamber) where the constituent layers of the stack 101 are formed (e.g., epitaxially grown) without removing the substrate 102 from the manufacturing equipment.

In one embodiment, the stack 101 of the IC device 100 includes a buffer layer 104 formed on the substrate 102. The buffer layer 104 may provide a crystal structure transition between the substrate 102 and other components (e.g., barrier layer 106) of the IC device 100, thereby acting as a buffer or isolation layer between the substrate 102 and other components of the IC device 100. For example, the buffer layer 104 may provide stress relaxation between the substrate 102 and other lattice-mismatched materials (e.g., the barrier layer 106). In some embodiments, the buffer layer 104 may serve as a channel for mobile charge carriers of a transistor. The buffer layer 104 may be epitaxially coupled with the substrate 102. In other embodiments, a nucleation layer (not shown) may intervene between the substrate 102 and the buffer layer 104. The buffer layer 104 may be composed of a plurality of deposited films or layers in some embodiments.

In some embodiments, the buffer layer 104 may include a group III-nitride-based material such as, for example, gallium nitride (GaN). The buffer layer 104 may have a thickness from 1 to 2 microns in a direction that is substantially perpendicular to a surface of the substrate 102 upon which the buffer layer 104 is formed. The buffer layer 104 may include other suitable materials and/or thicknesses in other embodiments.

The stack 101 may further include a barrier layer 106 (sometimes referred to as a “supply layer”) formed on the buffer layer 104. A heterojunction may be formed between the barrier layer 106 and the buffer layer 104. The barrier layer 106 may have a bandgap energy that is greater than a bandgap energy of the buffer layer 104. The barrier layer 106 may be a wider bandgap layer that supplies mobile charge carriers and the buffer layer 104 may be a narrower bandgap layer that provides a channel or pathway for the mobile charge carriers.

The barrier layer 106 may be composed of any of a variety of suitable material systems such as, for example, group III-nitride-based material systems. The barrier layer 106 may include, for example, aluminum (Al), indium (In), gallium (Ga), and/or nitrogen (N). In some embodiments, the barrier layer 106 may be composed of a single layer of a single material. For example, in one embodiment, the barrier layer 106 may be composed of a single layer of aluminum indium gallium nitride (AlₓIn₁₋ₓGa_{y}N), where x and y may be a value from 0 to 1 that represents relative quantities of the elements. In some embodiments, x may be a value greater than or equal to 0.5 to provide an aluminum content for oxidation processes described herein. The barrier layer 106 may include binary (e.g., AlN), tertiary (e.g., AlInN or AlGaN), or quaternary materials (e.g., AlInGaN) in various embodiments.

In some embodiments, the barrier layer 106 may be composed of a plurality of deposited films or layers. For example, referring briefly to FIG. 2, an IC device 200 may include a barrier layer 106 that is composed of a first barrier layer 107 disposed on the buffer layer 104 and a second barrier layer 108 disposed on the first barrier layer 107, as can be seen. In some embodiments, the first barrier layer 107 may be composed of aluminum nitride (AlN) and the second barrier layer 108 may be composed of indium aluminum nitride (InAlN), aluminum gallium nitride (AlGaN), or indium gallium aluminum nitride (InGaAlN). The barrier layer 106 may include other materials or more layers (e.g., third barrier layer 109 of FIGS. 8 and 10) than depicted in other embodiments. The IC device 200 may comport with embodiments described in connection with the IC device 100 of FIG. 1.

Referring again to FIG. 1, a two-dimensional electron gas (2DEG) may be formed at an interface (e.g., the heterojunction) of the buffer layer 104 and the barrier layer 106 allowing current (e.g., the mobile charge carriers) to flow between a source terminal, hereinafter source 112, and a drain terminal, hereinafter drain 114. In some embodiments, the IC device 100 may be an Enhancement-mode (E-mode) device, which uses a positive gate voltage with respect to source voltage in order to pinch-off current flow in the IC device 100. In such embodiments, the barrier layer 106 may have a thickness, T, between an oxidized portion of the barrier layer 106 (hereinafter “barrier oxidation” or simply “oxidation 110”) and the buffer layer 104 that is less than a critical thickness, Tₒ, for 2DEG formation (e.g., below the critical thickness Tₒ, the 2DEG may not form). For example, the thickness T may be configured to inhibit formation of the 2DEG at a gate region of the channel disposed between a gate terminal (hereinafter “gate 118”) and the buffer layer 104 while allowing 2DEG formation to occur in access regions of the channel between the gate region and the source 112 and drain 114. In some embodiments, a thickness and/or aluminum content of the barrier layer 106 may be selected to ensure that all of the 2DEG in the gate region is removed for an IC device 100 that is either a Schottky gate device or a metal-insulator-semiconductor (MIS) gate device. In other embodiments, the IC device 100 may be a Depletion-mode (D-mode) device, which uses a negative gate voltage with respect to source voltage in order to pinch-off current flow in the IC device 100.

In some embodiments, the barrier layer 106 has a thickness Tin the gate region that is less than or equal to 30 angstroms. For example, a barrier layer 106 composed of single layer of AlGaN may have a thickness T in the gate region that is less than or equal to 20 angstroms. A barrier layer 106 composed of AlN and/or InAlN may have a thickness Tin the gate region that is less than or equal to 15 angstroms. In some embodiments, the barrier layer 106 may have a thickness T that is in a range of 10 angstroms to 20 angstroms. In some embodiments, the barrier layer 106 may have a thickness in a region external to the gate region ranging from 160 angstroms to 300 angstroms in a direction that is substantially perpendicular to a surface of the buffer layer 104 upon which the barrier layer 106 is formed. The barrier layer 106 may include other suitable materials and/or thicknesses in other embodiments.

According to various embodiments, the IC device 100 further includes oxidation 110 disposed in the barrier layer 106, as can be seen. The oxidation 110 may be formed by oxidizing material of the barrier layer 106 using an oxidation process (e.g., application of heat and oxygen to form aluminum oxide). In some embodiments, the oxidation 110 may serve as an insulating layer of the gate 118 to provide an E-mode device. The oxidation 110 may suppress gate current. Formation of the oxidation 110 by oxidizing the barrier layer 106 material may allow formation of an insulating layer (e.g., the oxidation 110) without inducing trap or other defect formation associated with conventional recess or deposition processes to form an insulating layer such as recessing the barrier layer 106 to the buffer layer 104 and depositing a dielectric material on the buffer layer 104.

In some embodiments, the oxidation 110 is part of the barrier layer 106 (e.g., first barrier layer 107 and second barrier layer 108 of FIG. 2), as can be seen. The oxidation 110 may be disposed between the gate 118 and the buffer layer 104, as can be seen. The oxidation 110 may have other shapes than depicted in some embodiments including circular or amorphous shapes.

According to various embodiments, the oxidation 110 may have a bandgap energy that is greater than a bandgap energy of the barrier layer 106 and/or the buffer layer 104. In an embodiment, the oxidation 110 may have a bandgap that is greater than or equal to 5 electron volts (eV). In some embodiments, the oxidation 110 may have a work function that inhibits formation of the 2DEG at the gate region disposed between the gate 118 and the buffer layer 104. The oxidation 110 may increase resistivity in the gate region (e.g., the channel) such that the oxidation 110 is configured to pinch-off the channel of the IC device 100.

The oxidation 110 may be composed of aluminum oxide (e.g., Al₂O₃) in some embodiments. Other suitable metal oxides may be used in other embodiments.

According to various embodiments, the oxidation 110 may have a thickness that is less than or equal to 200 angstroms. For example, the oxidation 110 may have a thickness that ranges from 25 angstroms to 200 angstroms in a direction that is substantially perpendicular to a surface of the buffer layer 104 upon which the barrier layer 106 is formed. Other thicknesses and types of materials can be used for the oxidation 110 in other embodiments.

The IC device 100 may further include a gate terminal (hereinafter “gate 118”) disposed on the oxidation 110, as can be seen. The gate 118 may include a dielectric film (hereinafter “gate dielectric 118b”) and gate electrode 118a coupled with the oxidation 110. The gate 118 may be configured to control the channel of the IC device 100 (e.g., control an on/off state of the IC device 100). In some embodiments, the gate 118 may serve as a connection terminal for the IC device 100 and may be in direct physical contact with the barrier layer 106 and the oxidation 110, as can be seen. In some embodiments, the gate 118 may be formed on a dielectric layer 116 such as, for example, silicon nitride (SiN) or another dielectric material that is formed on barrier layer 106, as can be seen. In other embodiments, the IC device 100 may not include the gate dielectric 118b and/or the dielectric layer 116 at all. The gate 118 may be formed on the barrier layer 106 in some embodiments.

The gate 118 may have a trunk or bottom portion that is coupled with the oxidation 110 and a top portion that extends away from the trunk portion in opposing directions that are substantially parallel to a surface of the substrate 102 upon which the stack 101 is fabricated, as can be seen. Such configuration of the trunk portion and top portion of the gate 118 may be referred to as a T-shaped field-plate gate. That is, in some embodiments, the gate 118 may have an integrated field-plate (e.g., the top portion of the gate 118), which may increase a breakdown voltage and/or reduce an electric field between the gate 118 and the drain 114. The integrated field-plate may facilitate higher voltage operation of the IC device 100.

The gate electrode 118a may provide an electrical pathway for application of a threshold voltage to the IC device 100. The gate dielectric 118b may be disposed between the gate electrode 118a and the barrier layer 106 and/or between the gate electrode 118a and the oxidation 110, in some embodiments. The gate electrode 118a may be composed of an electrically conductive material such as a metal. In some embodiments, the gate electrode 118a may be composed of nickel (Ni), platinum (Pt), iridium (Ir), molybdenum (Mo), gold (Au), and/or aluminum (Al). In an embodiment, a material including Ni, Pt, Ir, or Mo is disposed in the trunk portion of the gate 118 to provide a gate contact with the barrier layer 106 and a material including Au is disposed in the top portion of the gate 118 to ensure conductivity and low resistance of the gate 118.

In various embodiments, the gate dielectric 118b may include, for example, silicon nitride (SiN), silicon oxide (SiO₂), aluminum oxide (Al₂O₃), and/or hafnium oxide (HfO₂). The gate dielectric 118b may include other materials in other embodiments.

The gate dielectric 118b may be formed by depositing a gate dielectric 118b material on the oxidation 110 using any suitable process such as, for example, chemical vapor deposition (CVD) and/or atomic layer deposition (ALD). In some embodiments, the gate dielectric 118 and the oxidation 110 are formed in situ. That is, the oxidation 110 may be formed in manufacturing equipment (e.g., a chamber of a deposition tool) that is used to deposit the gate dielectric 118b without removing the substrate 102 from the manufacturing equipment. In some embodiments, the manufacturing equipment includes an ALD or CVD deposition tool such as a plasma-enhanced CVD (PECVD) tool. Such in situ technique may reduce traps or other defects at an interface between the channel and the gate 118 of the IC device 100. In some embodiments, the gate dielectric 118 may not be used at all. The oxidation 110 may serve as the sole insulating layer of the gate 118 in some embodiments.

The IC device 100 may include a source 112 and drain 114 formed on the barrier layer 106. The source 112 and the drain 114 may extend through the barrier layer 106 into the buffer layer 104, as can be seen. According to various embodiments, the source 112 and the drain 114 are ohmic contacts. The source 112 and the drain 114 may be regrown contacts that may provide a relatively lower contact resistance than standard grown contacts.

The source 112 and the drain 114 may be composed of an electrically conductive material such as metal. In an embodiment, the source 112 and the drain 114 may include titanium (Ti), aluminum (Al), molybdenum (Mo), gold (Au), and/or silicon (Si). Other materials can be used in other embodiments.

In an embodiment, a distance D1 between the drain 114 and the gate 118 is greater than a distance S1 between the source 112 and the gate 118. The distance D1 may be a shortest distance between the drain 114 and the gate 118 and the distance S1 may be a shortest distance between the source 112 and the gate 118 in some embodiments. Providing a shorter distance S1 than distance D1 may increase a gate 118 to drain 114 breakdown voltage and/or reduce source 112 resistance.

A dielectric layer 122 may be formed on the gate 118 and/or the dielectric layer 116 in some embodiments, as can be seen. The dielectric layer 122 may include, for example, silicon nitride (SiN). Other materials can be used for the dielectric layer 122 in other embodiments. The dielectric layer 122 may substantially encapsulate the top portion of the gate 118 and serve as a passivation layer of the IC device 100 in some embodiments.

The IC device 100 may further include a field-plate 124 formed on the dielectric layer 122 to increase a breakdown voltage and/or reduce an electric field between the gate 118 and the drain 114. The field-plate 124 may be electrically coupled with the source 112 using an electrically conductive material 126. The electrically conductive material 126 may include a metal such as, for example, gold (Au) that is deposited as an electrode or trace-like structure on the dielectric layer 122. Other suitable materials may be used for the electrically conductive material 126 in other embodiments.

The field-plate 124 may be composed of an electrically conductive material such as a metal and may include materials described in connection with the gate 118. The field-plate 124 may be capacitively coupled with the gate 118 through the dielectric layer 122. In some embodiments, a shortest distance between the field-plate 124 and the gate 118 ranges from 1000 angstroms to 2000 angstroms. The field-plate 124 may be formed over the gate 118 such that a portion of the field-plate 124 is not formed directly over the gate 118 to provide an overhanging region of the field-plate 124, as can be seen. In some embodiments, the overhanging region of the field-plate 124 extends beyond an edge of the top portion of the gate 118 by a distance H1. The distance H1 may range from 0.2 microns to 1 micron in some embodiments. Other values for H1 may be used in other embodiments.

According to various embodiments, the IC device 100 may be a high electron mobility transistor (HEMT). In some embodiments, the IC device 100 may be a Schottky device. In other embodiments, the IC device 100 may be a MIS field-effect transistor (MISFET). For example, the gate 118 may be configured to control switching of an E-mode switch device in some embodiments. The IC device 100 may be used for Radio Frequency (RF), logic, and/or power conversion applications. For example, the IC device 100 may provide an effective switch device for power-switch applications including power conditioning applications such as, for example, Alternating Current (AC)-Direct Current (DC) converters, DC-DC converters, DC-AC converters, and the like.

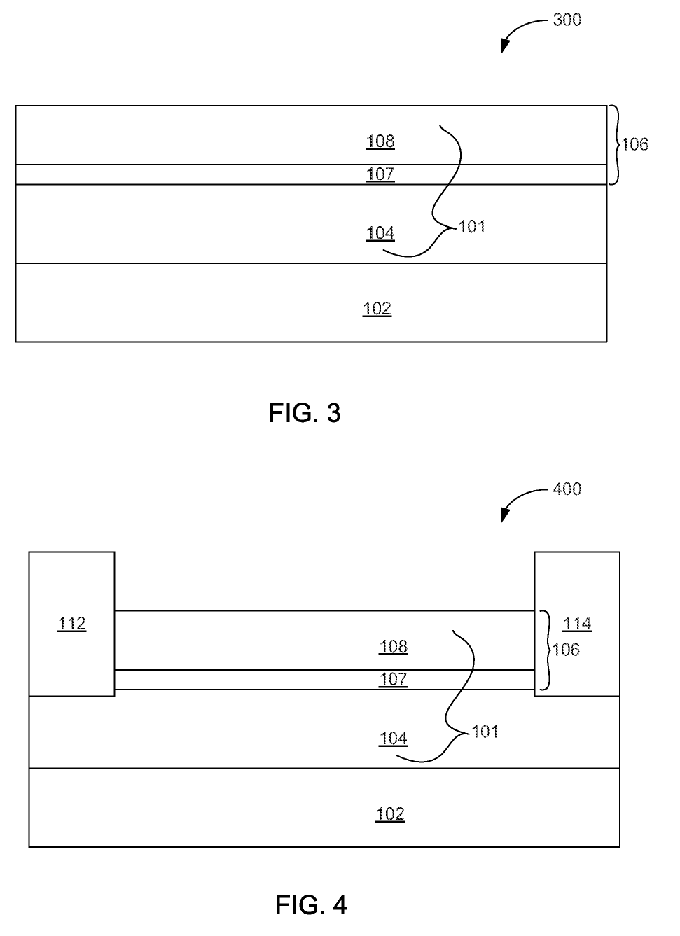

FIGS. 3-12 depict an IC device subsequent to various fabrication operations. Techniques and configurations described in connection with FIGS. 3-12 may comport with embodiments described in connection with FIGS. 1-2 and vice versa.

FIG. 3 schematically illustrates a cross-section view of an integrated circuit (IC) device 300 subsequent to formation of a stack of layers (e.g., stack 101) on a substrate 102, according to various embodiments. According to various embodiments, the IC device 300 may be fabricated by depositing a buffer layer 104 on the substrate 102 and depositing a barrier layer 106 on the buffer layer 104. The barrier layer 106 may include a first barrier layer 107 deposited on the buffer layer 104 and a second barrier layer 108 deposited on the first barrier layer 107. Additional barrier layers such as, for example, third barrier layer 109 of FIGS. 8 and 10 may be deposited on the second barrier layer 108 in some embodiments. The layers of the stack 101 may be deposited using an epitaxial deposition process such as, for example, molecular beam epitaxy (MBE), atomic layer epitaxy (ALE), chemical beam epitaxy (CBE) and/or metal-organic chemical vapor deposition (MOCVD). Other deposition processes may be used in other embodiments.

FIG. 4 schematically illustrates a cross-section view of an integrated circuit (IC) device 400 subsequent to formation of a source 112 and drain 114, according to various embodiments. The source 112 and drain 114 may be formed on the barrier layer 106 (e.g., on the second barrier layer 108) in various embodiments. In an embodiment, materials such as one or more metals are deposited on the barrier layer 106 in an area where the source 112 and drain 114 are to be formed using, e.g., an evaporation process. The materials used to form the source 112 and the drain 114 may include metals deposited in the following order: titanium (Ti) followed by aluminum (Al), which is followed by molybdenum (Mo), which is followed by titanium (Ti), which is followed by gold (Au). The deposited materials may be heated (e.g., to about 850° C. for about 30 seconds using a rapid thermal anneal process) to cause the materials to penetrate and fuse with underlying material of the barrier layer 106 (e.g., first barrier layer 107 and second barrier layer 108) and/or the buffer layer 104. In embodiments, each of the source 112 and the drain 114 extends through the barrier layer 106 and into the buffer layer 104. A thickness of the source 112 and the drain 114 may range from 1000 angstroms to 2000 angstroms. Other thicknesses for the source 112 and the drain 114 can be used in other embodiments.

The source 112 and the drain 114 may be formed by a regrowth process to provide ohmic contacts having a reduced contact resistance or reduced on-resistance. In the regrowth process, material of the barrier layer 106 and/or the buffer layer 104 may be selectively removed (e.g., etched) in areas where the source 112 and the drain 114 are to be formed. A highly doped material (e.g., n++ material) may be deposited in the areas where the layers have been selectively removed. The highly doped material of the source 112 and drain 114 may be a similar material as the material used for the buffer layer 104 or barrier layer 106. For example, in a system where the buffer layer 104 includes GaN, a GaN-based material that is highly doped with silicon (Si) may be epitaxially deposited in the selectively removed areas to a thickness of 400 angstroms to 700 angstroms. The highly doped material can be epitaxially deposited by molecular beam epitaxy (MBE), atomic layer epitaxy (ALE), chemical beam epitaxy (CBE), or metal-organic chemical vapor deposition (MOCVD), or suitable combinations thereof. Other materials, thicknesses, or deposition techniques for the highly doped material can be used in other embodiments. One or more metals including, e.g., titanium (Ti) and/or gold (Au) can be formed/deposited on the highly doped material at a thickness ranging from 1000 angstroms to 1500 angstroms using, e.g., a lift-off process. Other materials, thicknesses, and/or techniques for the one or more metals can be used in other embodiments.

In some embodiments, the source 112 and the drain 114 may be formed by an implantation process that uses implantation techniques to introduce an impurity (e.g., silicon) to provide a highly doped material in the source 112 and the drain 114. After implantation, the source 112 and the drain 114 may be annealed at a high temperature (e.g., 1100° C.-1200° C.). The regrowth process may preferably avoid the high temperature associated with the post-implantation anneal.

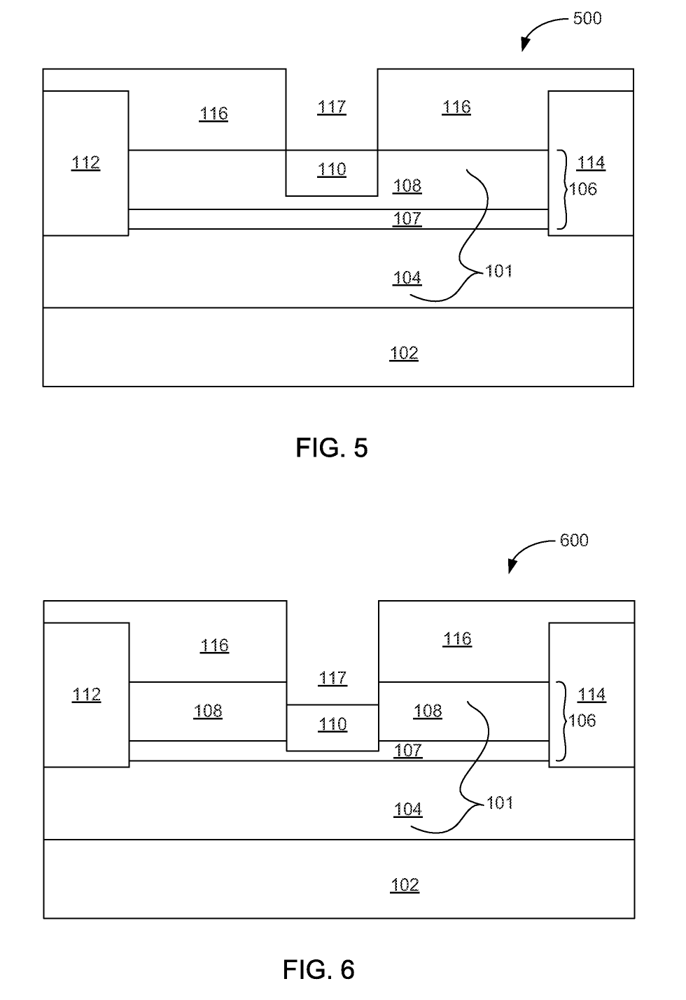

FIGS. 5-11 describe alternative processing techniques and configurations for forming an oxidized portion (e.g., oxidation 110) of the barrier layer 106. Techniques and configurations described in connection with FIGS. 5-11 may be suitably combined in some embodiments.

FIG. 5 schematically illustrates a cross-section view of an IC device 500 subsequent to forming an oxidized portion (e.g., oxidation 110) of the barrier layer 106 without recessing the barrier layer 106, according to various embodiments. In some embodiments, a dielectric layer 116 may be formed on the stack 101. The dielectric layer 116 may be patterned (e.g., by etch and/or lithography processes) to provide an opening 117 in the dielectric layer 116. In some embodiments, the dielectric layer 116 is recessed to expose material of the barrier layer 106. The material of the barrier layer 106 may not be recessed in some embodiments.

The dielectric layer 116 may serve as a mask during an oxidation process that forms the oxidation 110. For example, the dielectric layer 116 may prevent or inhibit oxidation of the barrier layer 106 beneath the dielectric layer 116 and allow oxidation of the barrier layer 106 through the opening 117 in an area of the barrier layer 106 that is adjacent to the opening 117.

In some embodiments, the barrier layer 106 may include multiple layers. For example, a first barrier layer 107 may be formed on the buffer layer 104 and a second barrier layer 108 may be formed on the first barrier layer 107. In some embodiments, the first barrier layer 107 may be composed of aluminum nitride (AlN) and the second barrier layer 108 may be composed of aluminum indium nitride (AlₓIn₁₋ₓN). Other materials may be used in other embodiments.

The oxidation 110 may extend only into the second barrier layer 108, as depicted, in some embodiments. In other embodiments, the oxidation 110 may extend into the first barrier layer 107. In other embodiments, the barrier layer 106 may be composed of a single layer. In some embodiments, the first barrier layer 107 as described in connection with FIG. 5 is not used at all.

The oxidation process used to form the oxidation 110 may include applying oxygen (O₂) and/or ozone (O₃) to the barrier layer 106 under controlled temperature and pressure conditions. For example, subsequent to forming the opening 117 in the dielectric layer 116, the substrate 102 may be placed in a deposition tool such as an ALD or PECVD equipment and an O₂/O₃ gas flow may be applied at a temperature from 150° C. to 350° C. at a pressure from 50 Torr to 900 Torr for 15 to 45 minutes. In one embodiment, the oxidation process may include applying O₂/O₃ gas at a temperature of 250° C. at a pressure of 90 Torr for 30 minutes. The oxidation process may combine the oxygen with aluminum (Al) of the barrier layer 106 to form aluminum oxide. The oxidation process used to form the oxidation 110 of FIGS. 6-11 may comport with embodiments described in connection with FIG. 5.

FIG. 6 schematically illustrates a cross-section view of an IC device 600 subsequent to recessing a barrier layer 106 and forming an oxidized portion (e.g., oxidation 110) of the barrier layer 106, according to various embodiments. In some embodiments, a dielectric layer 116 may be deposited on the barrier layer 106 and patterned with an opening 117. In some embodiments, the dielectric layer 116 may serve as a hard mask or gate mask. That is, material of the barrier layer 106 may be recessed through the opening 117 using an etch process that selectively removes the material of the barrier layer 106. In the depicted embodiment, the recessing removes material of the second barrier layer 108 only. In other embodiments, the recessing may remove material of the first barrier layer 107 and/or the second barrier layer 108. The first barrier layer 107 and the second barrier layer 108 may comport with embodiments described in connection with FIG. 5.

Subsequent to recessing the barrier layer 106, the oxidation 110 may be formed by using an oxidation process to oxidize material of the barrier layer 106 as described herein. The oxidation 110 may extend into the first barrier layer, as can be seen, in some embodiments. In other embodiments, the oxidation 110 may not extend into the first barrier layer 107, similar to the embodiment depicted in connection with FIG. 5. In still other embodiments, the oxidation 110 may extend to the buffer layer 104. In some embodiments, the barrier layer 106 may be composed of a single layer.

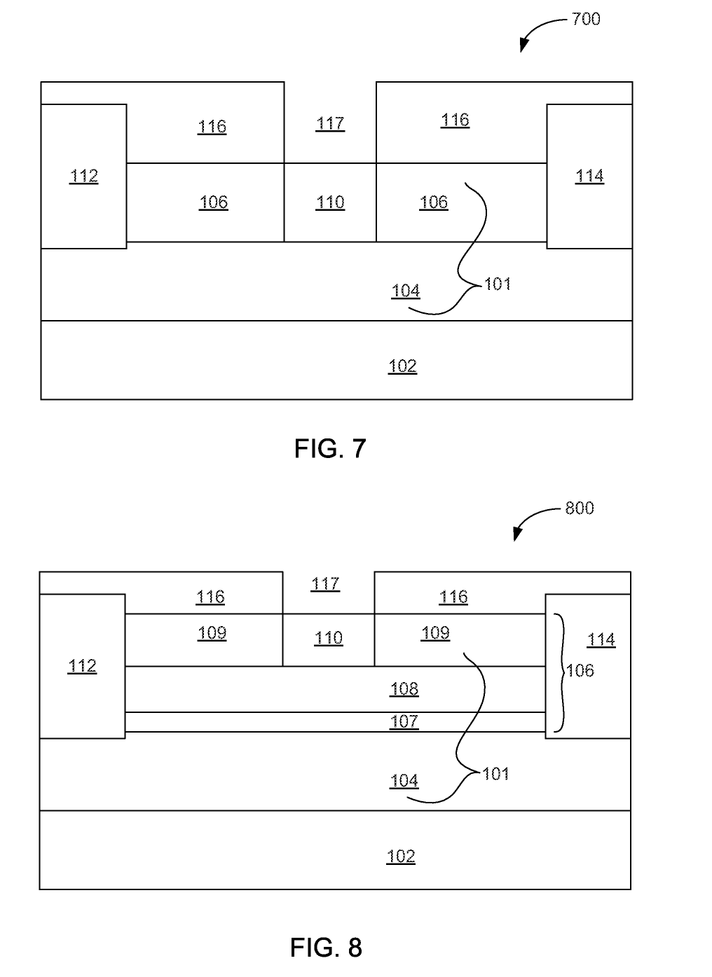

FIG. 7 schematically illustrates a cross-section view of another IC device 700 subsequent to forming an oxidized portion (e.g., oxidation 110) of a barrier layer 106 without recessing the barrier layer 106, according to various embodiments. A dielectric layer 116 may be formed on stack 101 and patterned with an opening 117 to allow oxidation of the underlying barrier layer 106 to form oxidation 110.

In some embodiments, materials for the buffer layer 104 and the barrier layer 106 are selected to facilitate depth control of the oxidation front. For example, the barrier layer 106 may have a significantly higher aluminum content than the buffer layer 104 such that the oxidation process stops or greatly slows down upon reaching the buffer layer 104. The lower aluminum content layer that underlies a higher aluminum content layer may be referred to as an oxidation-stop layer. In some embodiments, the buffer layer 104 may include gallium nitride (GaN) and the barrier layer 106 may include aluminum nitride (AlN). Other suitable materials may be used in other embodiments.

FIG. 8 schematically illustrates a cross-section view of an IC device 800 subsequent to forming an oxidized portion (e.g., oxidation 110) of a barrier layer (e.g., third barrier layer 109) over another barrier layer (e.g., second barrier layer 108) that serves as an oxidation-stop layer during an oxidation process, according to various embodiments. The stack 101 may include a buffer layer 104, first barrier layer 107, second barrier layer 108, and third barrier layer 109, coupled as can be seen.

In some embodiments, the second barrier layer 108 may have a lower aluminum content relative to the third barrier layer 109 such that the second barrier layer 108 serves as an oxidation-stop layer during an oxidation process that forms the oxidation 110. In some embodiments, the first barrier layer 107 may be composed of AlN, the second barrier layer 108 may be composed of Al_{y}Ga_{1-y}N, and the third barrier layer 109 may be composed of AlₓIn₁₋ₓN where x>0.5 and y<0.5. Other materials may be used for the first barrier layer 107, second barrier layer 108, and/or third barrier layer 109 in other embodiments. In some embodiments, the first barrier layer 107 may not be used at all (e.g., the second barrier layer 108 may be formed on the buffer layer 104).

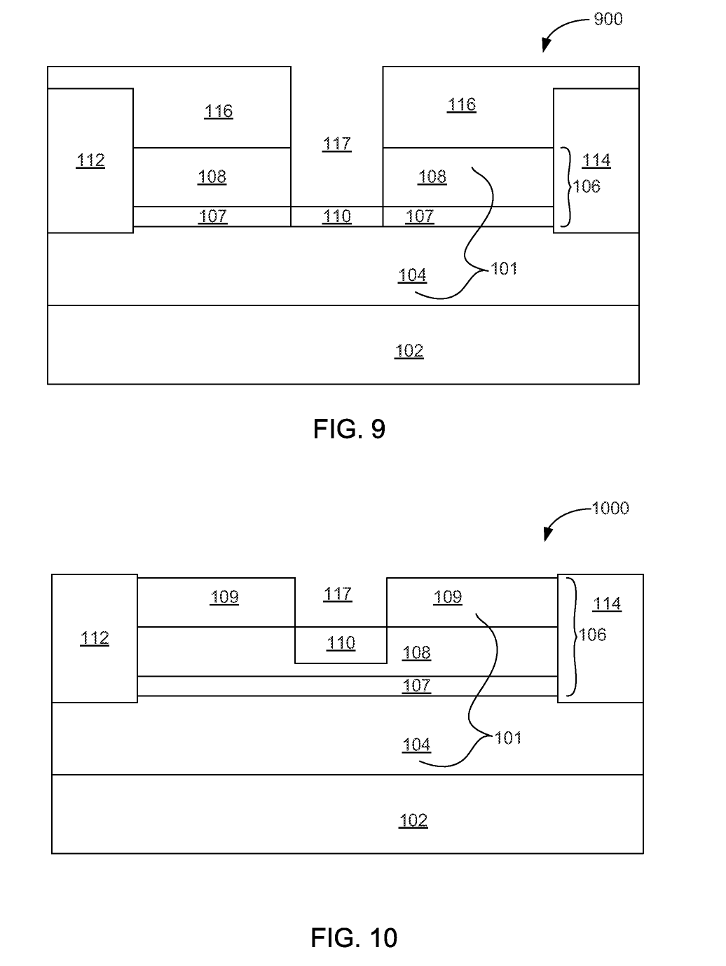

FIG. 9 schematically illustrates a cross-section view of an IC device 900 subsequent to forming an oxidized portion (e.g., oxidation 110) of a barrier layer 106 that serves as an etch-stop layer during a recessing process, according to various embodiments. The stack 101 may include a buffer layer 104, first barrier layer 107, and second barrier layer 108, coupled as can be seen. The second barrier layer 108 may have a lower aluminum content relative to the first barrier layer 107 such that the first barrier layer 107 serves as an etch-stop layer during a recessing process that removes material of the second barrier layer 108. For example, a selective etch process may be used that selectively removes material having lower aluminum content relative to material having higher aluminum content. In some embodiments, the first barrier layer 107 is composed of AlN or AlₓIn₁₋ₓN and the second barrier layer 108 is composed of Al_{y}Ga_{1-y}N. In some embodiments, x>0.5 and y<0.5.

A dielectric layer 116 may or may not be used as a gate mask in connection with IC device 900 of FIG. 9. For example, a photosensitive material may be deposited and patterned on the second barrier layer 108 with an opening to allow recessing of the second barrier layer 108 through the opening. The second barrier layer 108 having a relatively lower aluminum content may serve as a mask for oxidizing the first barrier layer 107 having a relatively higher aluminum content. In some embodiments, the buffer layer 104 may serve as an oxidation-stop layer for an oxidation process that oxidizes material of the first barrier layer 107 through the opening 117 in the second barrier layer 108 to form the oxidation 110.

FIG. 10 schematically illustrates a cross-section view of another IC device 1000 subsequent to forming an oxidized portion (e.g., oxidation 110) of a barrier layer 106 that serves as an etch-stop layer during a recessing process, according to various embodiments. The stack 101 may include a buffer layer 104, a first barrier layer 107, a second barrier layer 108, and a third barrier layer 109, coupled as can be seen.

The second barrier layer 108 may serve as an etch-stop layer for a recessing process that removes material of the third barrier layer 109 according to techniques described in connection with FIG. 9. The third barrier layer 109 may serve as a mask (e.g., oxidation mask) for an oxidation process that is used to form the oxidation 110 in the second barrier layer 108. In some embodiments, the first barrier layer 107 is composed of AlN, the second barrier layer 108 is composed of AlₓIn₁₋ₓN, and the third barrier layer 109 is composed of Al_{y}Ga_{1-y}N. In some embodiments, x>0.5 and y<0.5. In some embodiments, the first barrier layer 107 may not be used at all.

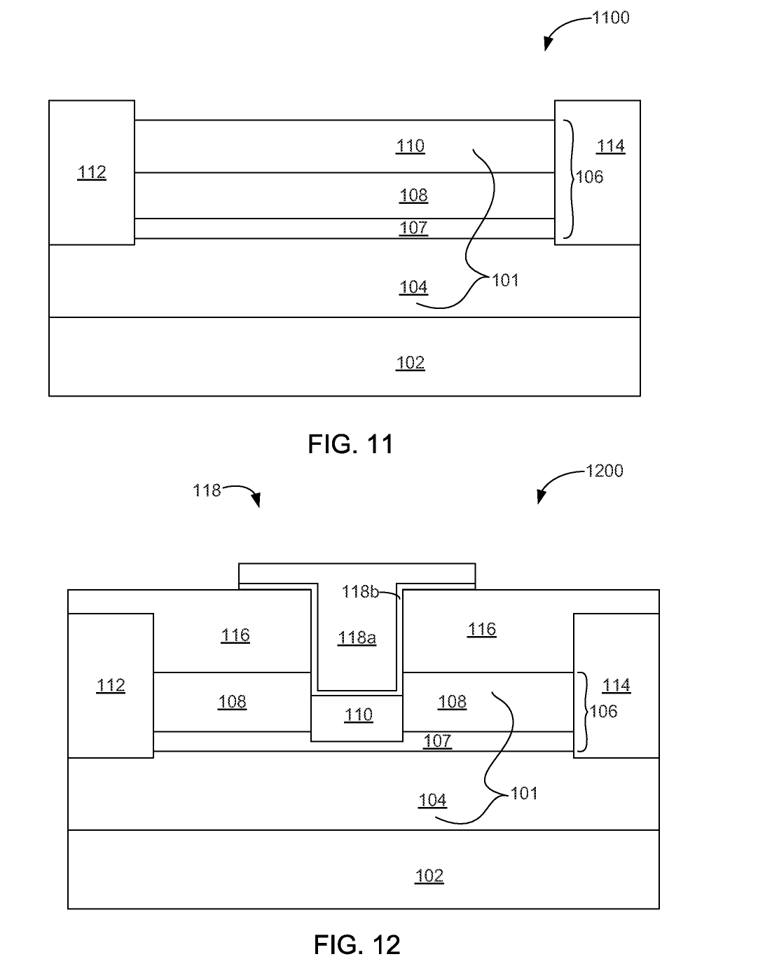

FIG. 11 schematically illustrates a cross-section view of another IC device 1100 subsequent to oxidizing a top barrier layer (e.g., oxidation 110), according to various embodiments. In some embodiments, the stack 101 may include a first barrier layer 107, a second barrier layer 108, and a third barrier layer (e.g., third barrier layer 109 of FIG. 8 before being oxidized) that is oxidized to form oxidation 110 as can be seen. The first barrier layer 107 may be composed of AlN, the second barrier layer 108 may be composed of Al_{y}Ga_{1-y}N, and the third barrier layer prior to being oxidized to form oxidation 110 may be composed of AlN or AlₓIn₁₋ₓN, in some embodiments. In some embodiments, x>0.5 and y<0.5. The third barrier layer (or top barrier layer) may be exposed to oxygen or ozone using oxidation techniques described herein to form oxidation 110, which may serve as a passivation layer. In some embodiments, the top barrier layer may be completely or partially oxidized to form the passivation layer. A passivation layer formed by oxidation may have fewer defects (e.g., lower surface states, lower current collapse, etc.) relative to a passivation layer deposited using a deposition process such as, for example, PECVD, ALD, and the like.

FIG. 12 schematically illustrates a cross-section view of an IC device 1200 subsequent to formation of a gate terminal (e.g., gate 118) on the oxidized portion (e.g., oxidation 110) of a barrier layer 106, according to various embodiments. Although the gate 118 is depicted as being formed on oxidation 110 configured as described in connection with FIG. 6, the gate 118 may also be similarly formed on the oxidation 110 configured as described in connection with FIG. 5 and FIGS. 7-11 in other embodiments. The gate 118 may include a gate electrode 118a and a gate dielectric 118b

In some embodiments, the gate dielectric 118b may be formed by depositing a dielectric material on the oxidation 110 and, in some cases, on exposed portions of the barrier layer 106, as can be seen. The material of the gate dielectric 118b may, for example, be composed of silicon nitride (SiN), silicon oxide (SiO₂), aluminum oxide (Al₂O₃), and/or hafnium oxide (HfO₂). Other materials may be used to form the gate dielectric 118b in other embodiments.

In some embodiments, the gate dielectric 118b is formed in situ with the oxidation 110. For example, the gate dielectric 118b may be formed in a deposition tool such as ALD or PECVD equipment that is used to carry out the oxidation process to form the oxidation 110. In some embodiments, the substrate 102 may be placed in a deposition tool such as ALD or PECVD equipment and the oxidation process may be used to form the oxidation 110 by applying oxygen (O₂) and/or ozone (O₃) to the barrier layer 106 under controlled temperature and pressure conditions as described herein. The substrate 102 may not be removed from the deposition tool until the gate dielectric 118b has been deposited on the oxidation 110.

In some embodiments, the gate dielectric 118b may be formed by depositing layers of material on the oxidation to a desired thickness using controlled temperature, pressure, and time. For example, the temperature may include a range from 150° C. to 350° C. and may be about 250° C. in some embodiments. The pressure and time may include conventional ranges for depositing a gate dielectric material.

The gate electrode 118a may be formed by depositing an electrically conductive material onto the gate dielectric 118b. The electrically conductive material may be deposited by any suitable deposition process including, for example, evaporation, atomic layer deposition (ALD) and/or chemical vapor deposition (CVD).

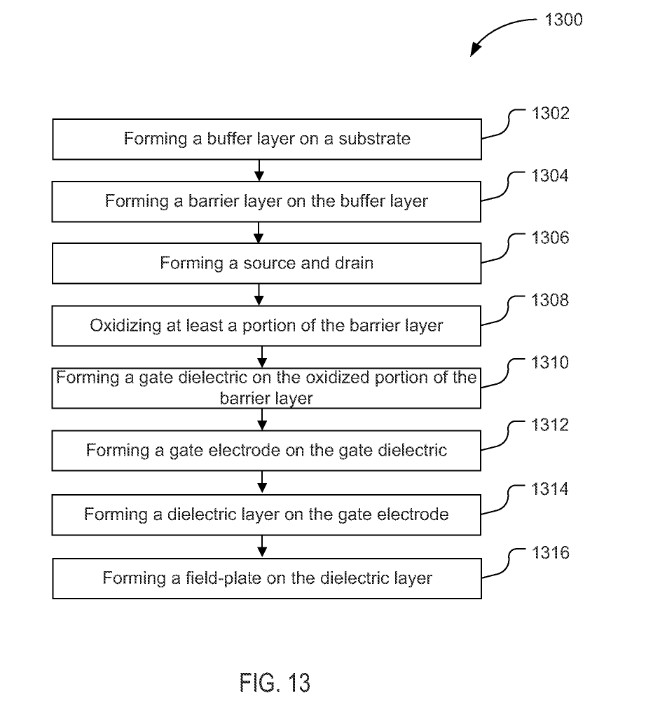

FIG. 13 is a flow diagram of a method 1300 for fabricating an IC device, according to various embodiments. The method 1300 may comport with techniques and configurations described in connection with FIGS. 1-12.

At 1302, the method 1300 includes forming a buffer layer (e.g., buffer layer 104 of FIG. 1) on a substrate (e.g., substrate 102 of FIG. 1). Forming the buffer layer may include epitaxially depositing a buffer layer material on the substrate. The buffer layer may be composed of multiple layers in some embodiments.

At 1304, the method 1300 may further include forming a barrier layer (e.g., barrier layer 106 of FIG. 1) on the buffer layer (e.g., buffer layer 104 of FIG. 1). Forming the barrier layer may include epitaxially depositing a barrier layer material on the buffer layer. The barrier layer may be composed of multiple layers (e.g., first barrier layer 107 of FIG. 2 and second barrier layer 108 of FIG. 2) in some embodiments. In other embodiments, the barrier layer may be formed by depositing a single layer of material.

At 1306, the method 1300 may further include forming a source (e.g., source 112 of FIG. 1) and drain (e.g., drain 114 of FIG. 1). The source and drain may be coupled with the barrier layer and may extend through the barrier layer into the buffer layer in some embodiments.

At 1308, the method 1300 may further include oxidizing at least a portion (e.g., oxidation 110 of FIG. 1) of the barrier layer. The barrier layer may be oxidized in situ in same equipment that is used to deposit a gate dielectric. The barrier layer may be oxidized according to techniques described in connection with FIGS. 5-11.

At 1310, the method 1300 may further include forming a gate dielectric (e.g., gate dielectric 118b of FIG. 1) on the oxidized portion of the barrier layer. The gate dielectric may be formed without removing the substrate from the equipment that is used to form the oxidation in order to reduce defects at a channel interface of the IC device.

At 1312, the method 1300 may further include forming a gate electrode on the gate dielectric. The gate electrode may be formed by depositing an electrically conductive material on the gate dielectric using any suitable technique.

At 1314, the method 1300 may further include forming a dielectric layer (e.g., dielectric layer 116 and/or 122 of FIG. 1) on the gate electrode. The dielectric layer may be deposited by any suitable deposition process. According to various embodiments, the dielectric layer may serve as a passivation layer for the IC device. In some embodiments, a dielectric layer may not be included in a final product of the IC device that is ready for sale or use.

At 1316, the method 1300 may further include forming a field-plate on the dielectric layer. The field-plate may be formed by depositing an electrically conductive material on the dielectric layer using any suitable deposition technique. Patterning processes such as lithography and/or etch processes can be used to selectively remove portions of the deposited electrically conductive material to form the field-plate. Other suitable techniques may be used in other embodiments.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

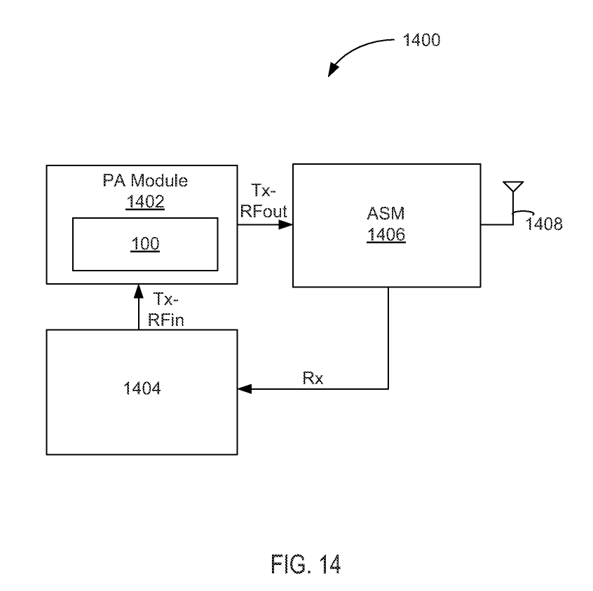

Embodiments of an IC device described herein, and apparatuses including such IC device may be incorporated into various other apparatuses and systems. A block diagram of an example system 1400 is illustrated in FIG. 14. As illustrated, the system 1400 includes a power amplifier (PA) module 1402, which may be a Radio Frequency (RF) PA module in some embodiments. The system 1400 may include a transceiver 1404 coupled with the power amplifier module 1402 as illustrated. The power amplifier module 1402 may include an IC device (e.g., the IC device 100 or other IC device) described herein.

The power amplifier module 1402 may receive an RF input signal, RFin, from the transceiver 1404. The power amplifier module 1402 may amplify the RF input signal, RFin, to provide the RF output signal, RFout. The RF input signal, RFin, and the RF output signal, RFout, may both be part of a transmit chain, respectively noted by Tx-RFin and Tx-RFout in FIG. 14.

The amplified RF output signal, RFout, may be provided to an antenna switch module (ASM) 1406, which effectuates an over-the-air (OTA) transmission of the RF output signal, RFout, via an antenna structure 1408. The ASM 1406 may also receive RF signals via the antenna structure 1408 and couple the received RF signals, Rx, to the transceiver 1404 along a receive chain.

In various embodiments, the antenna structure 1408 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 1400 may be any system including power amplification. The IC device (e.g., IC device 100) may provide an effective switch device for power-switch applications including power conditioning applications such as, for example, Alternating Current (AC)-Direct Current (DC) converters, DC-DC converters, DC-AC converters, and the like. In various embodiments, the system 1400 may be particularly useful for power amplification at high radio frequency power and frequency. For example, the system 1400 may be suitable for any one or more of terrestrial and satellite communications, radar systems, and possibly in various industrial and medical applications. More specifically, in various embodiments, the system 1400 may be a selected one of a radar device, a satellite communication device, a mobile handset, a cellular telephone base station, a broadcast radio, or a television amplifier system.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. An apparatus comprising:
a buffer layer disposed on a substrate, the buffer layer including gallium (Ga) and nitrogen (N);
a barrier layer disposed on the buffer layer, the barrier layer including aluminum (Al) and nitrogen (N), wherein the barrier layer includes an oxidized portion;
a gate dielectric disposed on the oxidized portion of the barrier layer; and
a gate electrode disposed on the gate dielectric, wherein the oxidized portion of the barrier layer is disposed in a gate region between the gate electrode and the buffer layer.

2. The apparatus of claim 1, wherein the oxidized portion of the barrier layer includes aluminum oxide (Al₂O₃).

3. The apparatus of claim 1, wherein the barrier layer is composed of multiple layers including a first layer epitaxially coupled with the buffer layer and a second layer epitaxially coupled with the first layer.

4. The apparatus of claim 3, wherein:
the first layer includes aluminum nitride (AlN);
the second layer includes indium aluminum nitride (InAlN), aluminum gallium nitride (AlGaN), or indium gallium aluminum nitride (InGaAlN); and
the oxidized portion of the barrier layer includes material of the first layer and material of the second layer.

5. The apparatus of claim 3, wherein:
the first layer includes a higher aluminum content relative to the second layer;
the first layer is an etch-stop layer for an etch process that removes material of the second layer; and
the oxidized portion of the barrier layer includes a section of the first layer.

6. The apparatus of claim 3, wherein:
the first layer includes a lower aluminum content relative to the second layer;
the first layer is an oxidation-stop layer for an oxidation process that forms the oxidized portion of the barrier layer; and
the oxidized portion of the barrier layer includes a section of the second layer.

7. The apparatus of claim 6, wherein:
the second layer is completely oxidized to form a passivation layer.

8. The apparatus of claim 1, wherein the barrier layer is composed of a single layer.

9. The apparatus of claim 1, wherein the oxidized portion of the barrier layer and the gate dielectric are formed in situ in a fabrication equipment that is used to deposit material of the gate dielectric.

10. The apparatus of claim 1, wherein:
the barrier layer has a thickness in a range of 10 angstroms to 200 angstroms.

11. The apparatus of claim 1, wherein:
the barrier layer has a first bandgap energy; and
the buffer layer has a second bandgap energy that is less than the first bandgap energy.

12. The apparatus of claim 1, further comprising:
a source coupled with the barrier layer; and
a drain coupled with the barrier layer, wherein the source and the drain extend through the barrier layer into the buffer layer.

13. The apparatus of claim 1, further comprising:
a dielectric material disposed on the barrier layer.

14. The apparatus of claim 1, wherein:
the gate dielectric includes hafnium oxide (HfO₂) or aluminum oxide (Al₂O₃);
the gate electrode is part of a T-shaped field-plate gate; and
the gate electrode includes nickel (Ni), platinum (Pt), iridium (Ir), molybdenum (Mo), or gold (Au).

15. The apparatus of claim 1, further comprising:
the substrate, the substrate including silicon (Si), silicon carbide (SiC), sapphire (Al₂O₃), gallium nitride (GaN), or aluminum nitride (AlN), wherein the buffer layer includes gallium nitride (GaN).

16. The apparatus of claim 1, wherein the gate electrode is coupled with the gate dielectric, the oxidized portion of the barrier layer, and the buffer layer to form a metal-insulator-semiconductor (MIS) junction.

17. The apparatus of claim 10, wherein the gate electrode is configured to control switching of an Enhancement mode (E-mode) high electron mobility transistor (HEMT) device.

18. A method comprising:
forming a buffer layer on a substrate, the buffer layer including gallium (Ga) and nitrogen (N);
forming a barrier layer on the buffer layer, the barrier layer including aluminum (Al) and nitrogen (N); and
oxidizing a portion of the barrier layer in a thin-film deposition chamber to provide gate insulation for a transistor device.

19. The method of claim 18, wherein:
oxidizing the portion of the barrier layer includes exposing the barrier layer to a gas including oxygen at a temperature in the range of 200° C. and 300° C. and a pressure in the range of 50 Torr to 150 Torr.

20. The method of claim 18, further comprising:
forming a gate dielectric on the oxidized portion of the barrier layer, wherein the oxidizing the portion of the barrier layer and forming the gate dielectric are performed in the same thin-film deposition chamber.

21. The method of claim 20, wherein the oxidizing the portion and forming the gate dielectric are performed without removing the substrate from the thin-film deposition chamber.

22. The method of claim 20, further comprising:
forming a gate electrode on the gate dielectric, wherein the oxidized portion of the barrier layer is disposed in a gate region between the gate electrode and the buffer layer.

23. The method of claim 20, wherein forming the gate dielectric includes depositing a gate dielectric material using atomic layer deposition (ALD) or plasma-enhanced chemical vapor deposition (PECVD).

24. The method of claim 18, further comprising:
removing material of the barrier layer to form an opening in the barrier layer prior to oxidizing the portion, wherein oxidizing the portion of the barrier layer is performed by oxidizing material of the barrier layer in the opening of the barrier layer.

25. The method of claim 24, further comprising:
depositing a dielectric layer on the barrier layer; and
removing material of the dielectric layer to form an opening in the dielectric layer, wherein removing the material of the barrier layer to form the opening in the barrier layer includes removing the material of the barrier layer through the opening in the dielectric layer.

26. The method of claim 24, wherein:
removing the material of the barrier layer is performed using a selective etch process; and
forming the barrier layer includes:
epitaxially depositing a first layer on the buffer layer; and
epitaxially depositing a second layer on the first layer, wherein the first layer includes a higher aluminum content relative to the second layer and the first layer is an etch-stop layer for the selective etch process.

27. The method of claim 18, wherein:
forming the buffer layer includes epitaxially depositing a buffer layer material on the substrate; and
forming the barrier layer includes epitaxially depositing a barrier layer material on the buffer layer.

28. The method of claim 18, further comprising:
forming a source and drain coupled with the barrier layer, wherein the source and the drain extend through the barrier layer into the buffer layer.

29. The method of claim 22, wherein:
the gate electrode is coupled with the gate dielectric, the oxidized portion of the barrier layer, and the buffer layer to form a metal-insulator-semiconductor (MIS) junction;
the transistor device is an Enhancement mode (E-mode) high electron mobility transistor (HEMT) device; and
the gate electrode is configured to control switching of the E-mode HEMT device.
